(19) United States
(12) Patent Application Publication
(10) Pub. No.: US 2026/0090296 A1
(43) Pub. Date: Mar. 26, 2026

(54) SEMICONDUCTOR DEVICE AND METHOD FOR MANUFACTURING SAME

(71) Applicants: Kabushiki Kaisha Toshiba, Tokyo (JP); Toshiba Electronic Devices & Storage Corporation, Tokyo (JP)

(72) Inventor: Yuuichi WAKABAYASHI, Nonoichi Ishikawa (JP)

(21) Appl. No.: 19/061,941

(22) Filed: Feb. 24, 2025

(30) Foreign Application Priority Data
Sep. 20, 2024 (JP) 2024-164314

(51) Int. Cl. H01L 21/02; H01L 21/324; H10D 30/66

(52) U.S. Cl. CPC H10P 14/6923; H10D 30/668; H10P 95/90

(57) ABSTRACT

A method for manufacturing a semiconductor device includes preparing a structure body including a semiconductor part, a trench being formed in the structure body. The trench extends along a first direction. The method includes forming a doped glass film at an upper surface of the structure body and at a surface of the trench, forming a resist pattern on the structure body and performing lithography, removing the doped glass film at a location other than a location at which the resist pattern remains, and performing annealing treatment of the structure body including the doped glass film that remains.

### CROSS-REFERENCE TO RELATED APPLICATIONS

This application is based upon and claims the benefit of priority from Japanese Patent Application No.2024-164314, filed on Sep. 20, 2024; the entire contents of which are incorporated herein by reference.

### FIELD

Embodiments described herein relate generally to a semiconductor device and a method for manufacturing the semiconductor device.

### BACKGROUND

Technology has been developed for semiconductor devices such as MOS (metal-oxide-semiconductors) and the like that have trench structures.

### BRIEF DESCRIPTION OF THE DRAWINGS

FIG. 1 is a plan view of a semiconductor device according to a first embodiment;

FIG. 2 is a flowchart showing a flow of a method for manufacturing the semiconductor device according to the first embodiment;

FIGS. 3 to 7 are cross-sectional views showing the method for manufacturing the semiconductor device according to the first embodiment;

FIGS. 8 to 10 are cross-sectional views showing a method for manufacturing a semiconductor device according to a modification 1;

FIGS. 11A to 13 are cross-sectional views showing a method for manufacturing a semiconductor device according to a modification 2;

FIG. 14 is a flowchart showing a flow of a method for manufacturing a semiconductor device according to a second embodiment; and

FIGS. 15 to 17 are cross-sectional views showing the method for manufacturing the semiconductor device according to the second embodiment.

### DETAILED DESCRIPTION

A method for manufacturing a semiconductor device according to an embodiment, the method includes preparing a structure body including a semiconductor part, a trench being formed in the structure body. The trench extends along a first direction. The method includes forming a doped glass film at an upper surface of the structure body and at a surface of the trench, forming a resist pattern on the structure body and performing lithography, removing the doped glass film at a location other than a location at which the resist pattern remains, and performing annealing treatment of the structure body including the doped glass film that remains.

Exemplary embodiments will now be described with reference to the drawings. The invention is not limited to the embodiments. The drawings are schematic or conceptual; and the relationships between the thickness and width of portions, the proportional coefficients of sizes among portions, etc., are not necessarily the same as the actual values thereof. In the specification of the application and the drawings, components similar to those described in regard to a drawing thereinabove are marked with like reference numerals, and a detailed description is omitted as appropriate.

An XYZ orthogonal coordinate system is used in the description of embodiments. Specifically, a direction from a drain electrode 41 toward a source electrode 42 is taken as a Z-direction. Two mutually-orthogonal directions perpendicular to the Z-direction are taken as an X-direction and a Y-direction.

Terminology in the specification such as, for example, “parallel”, “same”, and the like used to specify shapes, geometrical conditions, and their degree are construed to include ranges within which similar functions may be expected without being bound to strict meanings.

In the following description, the notations of n⁺, n⁻, p⁺, and p indicate relative levels of the impurity concentrations of the conductivity types. Specifically, a notation marked with “+” indicates that the impurity concentration is relatively higher than that of a notation not marked with either “+” or “−”; and a notation marked with “−” indicates that the impurity concentration is relatively lower than that of a notation without any mark. When both a p-type impurity and an n-type impurity are included in each region, these notations indicate relative levels of the net impurity concentrations after the impurities compensate each other. According to the embodiments below, each embodiment may be implemented by inverting the p-type and the n-type of each semiconductor region.

### 1. FIRST EMBODIMENT

### 1.1 Structure of Semiconductor Device 100

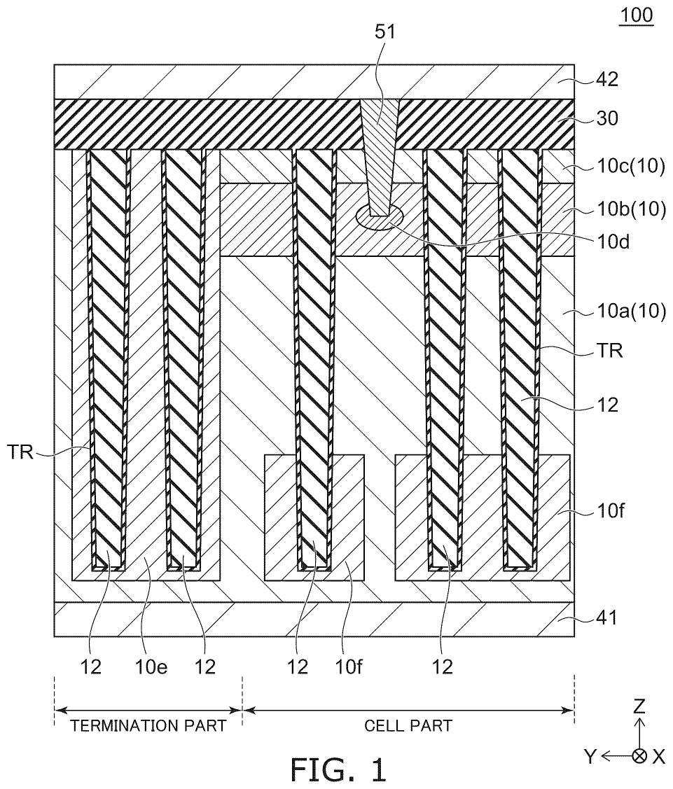

A semiconductor device 100 according to the embodiment will now be described with reference to FIG. 1.

FIG. 1 is a plan view of the semiconductor device 100 according to the embodiment. The semiconductor device 100 is, for example, a power MOSFET (Metal Oxide Semiconductor Field Effect Transistor). As shown in FIG. 1, the semiconductor device 100 includes a semiconductor part 10, the drain electrode 41 as a first electrode, and the source electrode 42 as a second electrode. The semiconductor device 100 includes a cell part that functions as, for example, a MOSFET and is a region through which a current mainly flows when a power supply is on, and a termination part that is located at the periphery of the cell part.

The semiconductor part 10 includes, for example, silicon and is located between the drain electrode 41 and the source electrode 42. The semiconductor part 10 includes a first semiconductor layer 10a of a first conductivity type, a second semiconductor layer 10b of a second conductivity type, a third semiconductor layer 10c of the first conductivity type, a fourth semiconductor layer 10d of the second conductivity type, a fifth semiconductor layer (a first impurity layer) 10e of the second conductivity type, and a sixth semiconductor layer (a second impurity layer) 10f of the second conductivity type. Although the first conductivity type is taken to be an n-type and the second conductivity type is taken to be a p-type as an example hereinbelow, the description is not limited thereto.

Multiple trenches TR that extend along the X-direction are formed in the semiconductor part 10. Although the trench TR is formed in a slender trench shape having a rectangular cross section as an example, the trench TR is not limited to the example. A gate electrode 12 and an insulating part 30 are located inside the trench TR.

The first semiconductor layer 10a includes, for example, an n⁺-type drift layer located at the upper surface of the drain electrode 41, and an n⁻-type drift layer located at the upper surface of the n⁺-type drift layer. The first semiconductor layer 10a extends between the drain electrode 41 and the source electrode 42.

The second semiconductor layer 10b is, for example, a p-type base layer. The second semiconductor layer 10b is located on the first semiconductor layer 10a.

The third semiconductor layer 10c is, for example, an n⁺-type source layer. The third semiconductor layer 10c is partially provided on the second semiconductor layer 10b. The third semiconductor layer 10c is electrically connected with the source electrode 42.

The fourth semiconductor layer 10d is, for example, a p⁺-type contact layer. The fourth semiconductor layer 10d is partially provided on the second semiconductor layer 10b. The fourth semiconductor layer 10d includes a second-conductivity-type impurity with a higher concentration than the second-conductivity-type impurity of the second semiconductor layer 10b. The source electrode 42 is electrically connected with the second semiconductor layer 10b, the third semiconductor layer 10c, and the fourth semiconductor layer 10d via a source contact 51.

The fifth semiconductor layer 10e is, for example, a p-type guard ring layer. The fifth semiconductor layer 10e is located at the periphery of the trench TR located in the termination part. The fifth semiconductor layer 10e extends from the periphery of the upper end portion to the periphery of the lower end portion of the trench TR.

The sixth semiconductor layer 10f is, for example, a p-type deep layer. The sixth semiconductor layer 10f is located at the periphery of the lower end portion of the trench TR located in the cell part. The height (i.e., the Z-direction length; similarly hereinbelow) of the p-type deep layer can be set as appropriate.

The gate electrode 12 extends in the X-direction inside the trench TR in the cell part. As an example, the gate electrode 12 may include polysilicon in which an impurity is introduced to silicon.

The insulating part 30 includes silicon oxide (SiO₂) and is located inside the trench TR and on the semiconductor part 10.

### 1.2 Method for Manufacturing Semiconductor Device 100

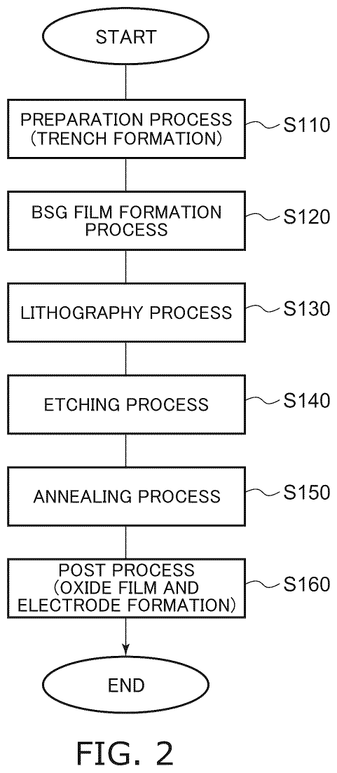

A method for manufacturing the semiconductor device 100 will now be described with reference to FIGS. 2 to 7.

FIG. 2 is a flowchart showing the flow of the method for manufacturing the semiconductor device according to the first embodiment.

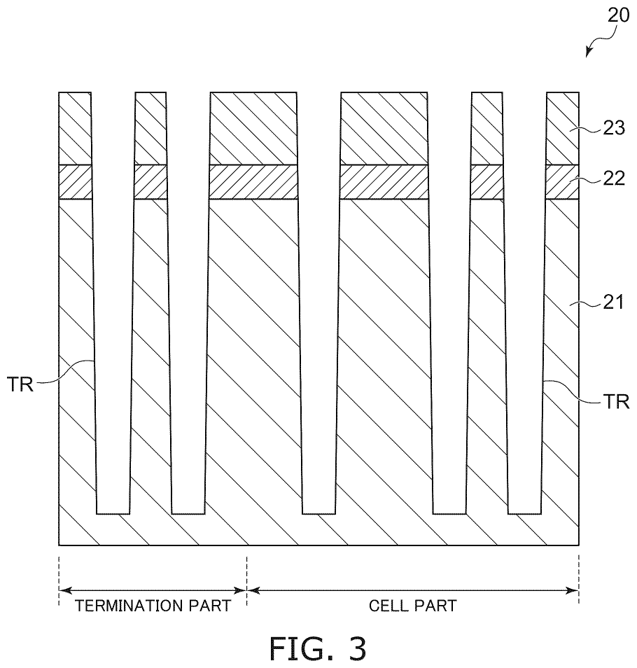

FIGS. 3 to 7 are cross-sectional views showing the method for manufacturing the semiconductor device according to the first embodiment.

According to the method for manufacturing the semiconductor device 100 as shown in FIG. 2, steps S110 to S160 are performed.

In step S110 as shown in FIG. 3, as a preparation process, a structure body 20 in which the trench TR is formed in a semiconductor part 21 is prepared. A SiO₂ film 22 and a SiN film 23 are located on the structure body 20. The SiO₂ film 22 and the SiN film 23 function as a mask member when forming the trench TR in the semiconductor part 21.

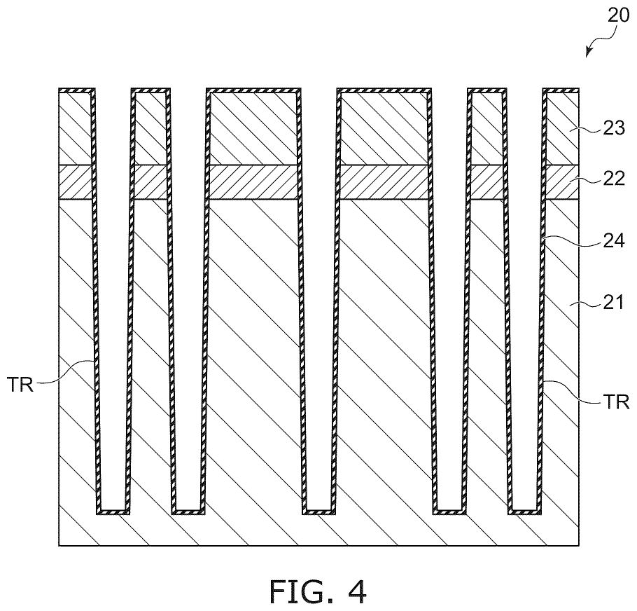

In step S120, a BSG film formation process is performed as shown in FIG. 4. In the BSG film formation process, a BSG (Borosilicate Glass) film 24 is formed at the upper surface of the structure body 20 and at the surface of the trench TR by, for example, CVD (Chemical Vapor Deposition). Known technology other than CVD may be used to form the BSG film 24. The BSG film is an example of doped glass film.

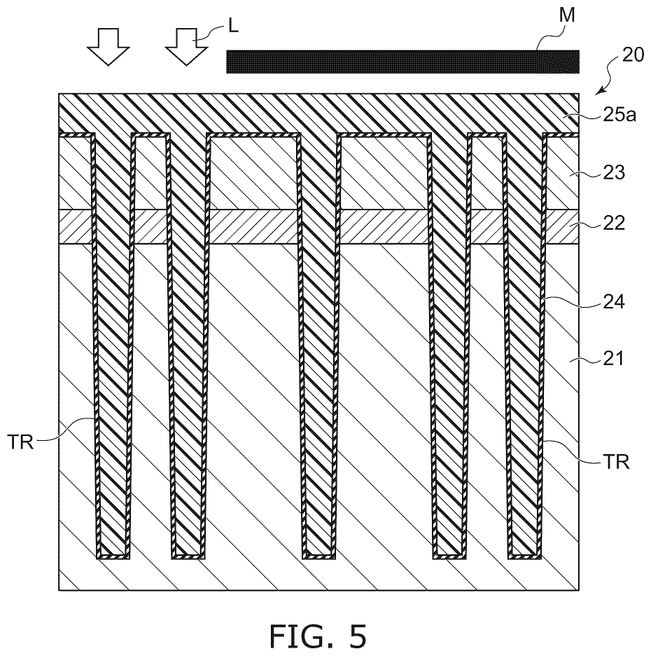

In step S130 as shown in FIG. 5, as a lithography process, a negative resist 25a for forming a resist pattern is coated onto the structure body 20, exposed to light L to form a desired pattern by using a mask M, and developed. As a result, the negative resist 25a that is cured by exposure remains inside the trench TR. For example, exposure to light generates cross-linking between molecules of the negative resist 25a, causing the negative resist 25a to become insoluble during development.

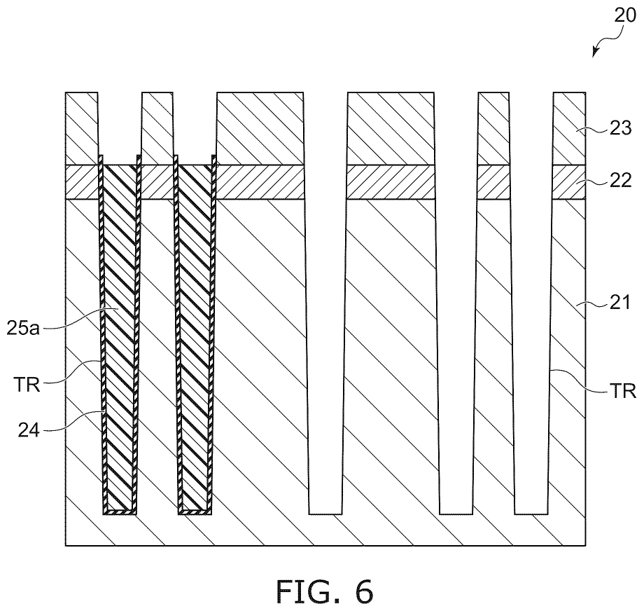

In step S140 as shown in FIG. 6, as an etching process, the negative resist 25a that remains inside the trench TR is caused to recede by CDE (Chemical Dry Etching). Then, wet etching of the BSG film 24 on the upper surface of the structure body 20 and on the surface of the trench TR is performed. As a result, the BSG film 24 is removed at other locations different from the locations at which the negative resist 25a remains inside the trench TR. Subsequently, the negative resist 25a that remains inside the trench TR is removed.

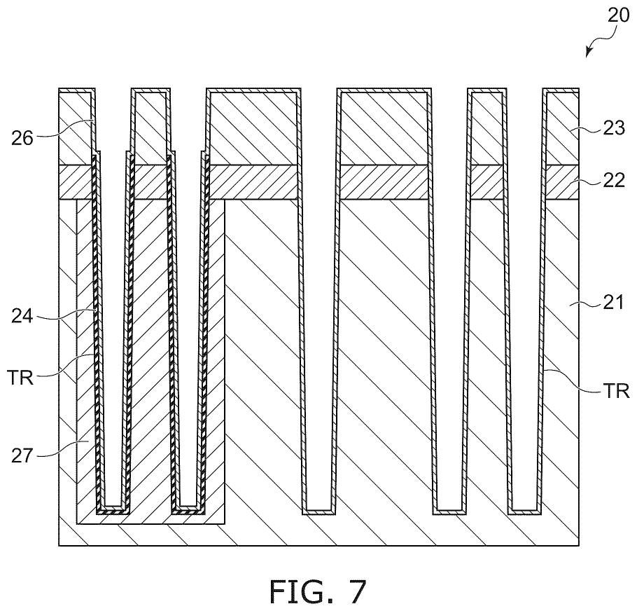

In step S150, an annealing process is performed as shown in FIG. 7. In the annealing process, first, a TEOS (Tetra Ethoxy Silane) film 26 is formed on the structure body 20 as a protective film by, for example, CVD. Then, heat treatment of the structure body 20 is performed. The conditions of the heat treatment may include, for example, maintaining a temperature of 900° C, to 1,200° C. for 10 minutes to 20 minutes. As a result, solid-state diffusion of boron from the remaining BSG film occurs, and a p-layer 27 is formed at the periphery of the trench TR located in the termination part. As described above, although solid-state diffusion of boron into the exposed silicon layer can be prevented by forming the TEOS film 26 as a protective film, the TEOS film 26 may not be formed.

As post processes in step S160, the BSG film 24 and the TEOS film 26 are removed by wet etching; and an oxide film is formed as the insulating part 30 at the upper surface of the structure body 20 and at the surface of the trench TR. Also, the gate electrode 12 is formed by forming a polysilicon layer inside the trench TR. The second semiconductor layer 10b, the third semiconductor layer 10c, and the fourth semiconductor layer 10d are formed by implanting impurities. The drain electrode 41 is provided at the lower surface of the semiconductor part 10; and the source electrode 42 and the source contact 51 are provided at the upper surface of the semiconductor part 10. The semiconductor device 100 is manufactured thereby.

### 1.3 Summary

Thus, in the semiconductor device 100 according to the embodiment, the p-layer region can be formed by solid-state diffusion after the trench TR is formed in the structure body 20. Therefore, p-layer regions that have different heights can be formed simultaneously. Also, by forming the p-layer by solid-state diffusion, epitaxial growth and ion implantation can be omitted, and crystal defects due to damage by the ion implantation can be suppressed. In ion implantation, if the width (i.e., the X-direction length or Y-direction) of the opening of the resist pattern is narrow and the ion beam passes through the opening, the ion beam easily strikes the edge of the resist pattern; the beam is undesirably scattered thereby, which causes the ions to lose energy before reaching the silicon wafer; and as a result, discrepancies occur in which the implantation depth is shallow. Therefore, for ion implantation, it is necessary to ensure a certain width of the resist pattern, whereas according to the embodiment, by using solid-state diffusion, the width of the trench TR formed by trench RIE can be narrow, and as a result, the pattern width of the p-layer formed by diffusing from the trench can be narrow. Concentration of the electric field on the oxide film at the bottom portion of the trench TR is relaxed by the p-layer formed at the periphery of the bottom portion of the trench TR. Also, a speedup effect, specifically, an increased rate of oxidation (enhanced oxidation) is obtained by forming the p-layer at the periphery of the bottom portion of the trench TR; and breakdown of the oxide film is suppressed.

### 1.4 Modification 1

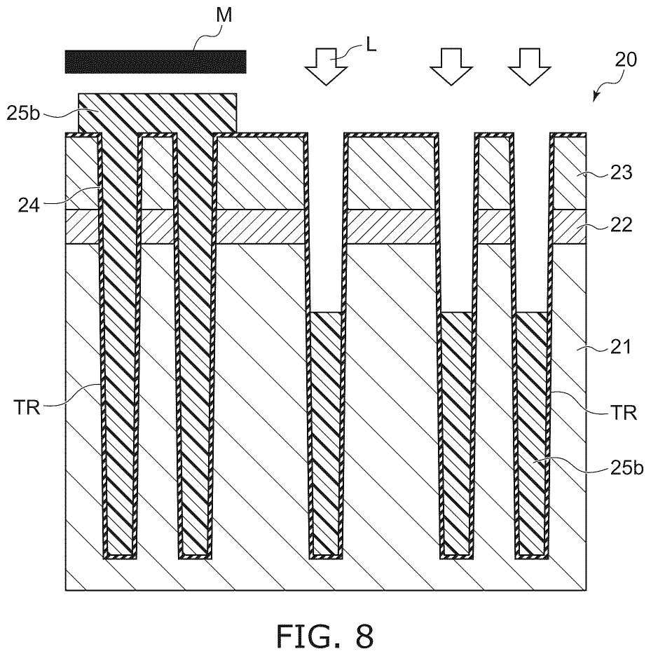

The semiconductor device 100 according to the embodiment will now be described with reference to FIGS. 8 to 10.

FIGS. 8 to 10 are cross-sectional views showing a method for manufacturing a semiconductor device according to a modification 1.

The lithography process of step S130 according to the modification 1 differs from that of the embodiments above. The modification 1 will now be described with focus on the differences.

In the lithography process of step S130 as shown in FIG. 8, a positive resist 25b for forming a resist pattern is coated onto the structure body 20, exposed by the light L to form a desired pattern by using the mask M, and developed. As a result, the positive resist 25b other than the portions dissolved by the exposure remains inside the trench TR.

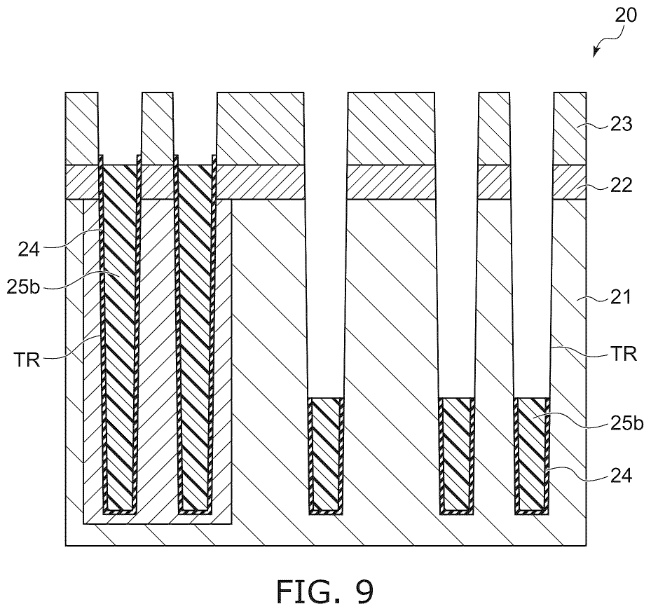

In the etching process of step S140 as shown in FIG. 9, the positive resist 25b that remains inside the trench TR is caused to recede by CDE (Chemical Dry Etching). As a result, the positive resists 25b that remain inside the multiple trenches TR can have different heights for different trenches TR. Subsequently, wet etching of the BSG film 24 on the upper surface of the structure body 20 and on the surface of the trench TR is performed. As a result, the BSG film 24 is removed at other locations different from the locations at which the positive resists 25b remain inside the trenches TR. Subsequently, the positive resists 25b that remain inside the trenches TR are removed.

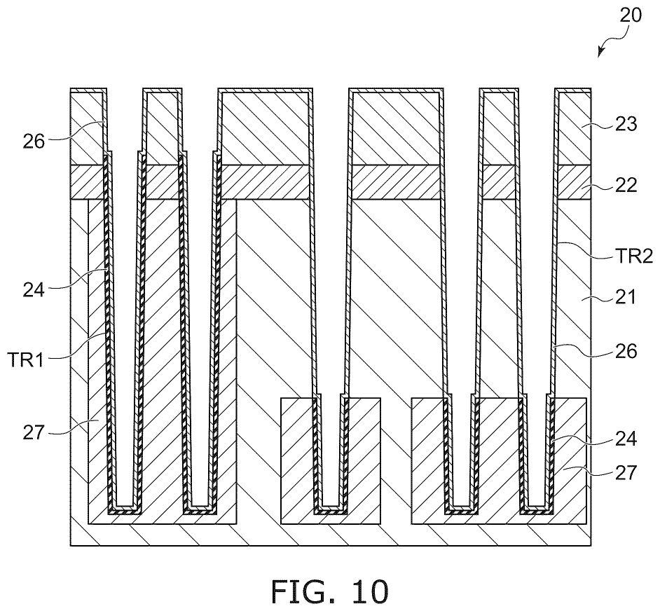

In the annealing process of step S150 as shown in FIG. 10, similarly to the embodiments above, the TEOS film 26 is formed as a protective film; and heat treatment of the structure body 20 is performed. As a result, solid-state diffusion of boron occurs from the remaining BSG film; and the p-layer 27 is formed at the peripheries of the trenches TR located in the termination part and the cell part. Thus, according to the modification 1, by using the positive resist 25b in the lithography process, the height of the p-layer 27 formed at the periphery of the trench can be different between a trench TR1 in the termination part and a trench TR2 in the cell part.

### 1.5 Modification 2

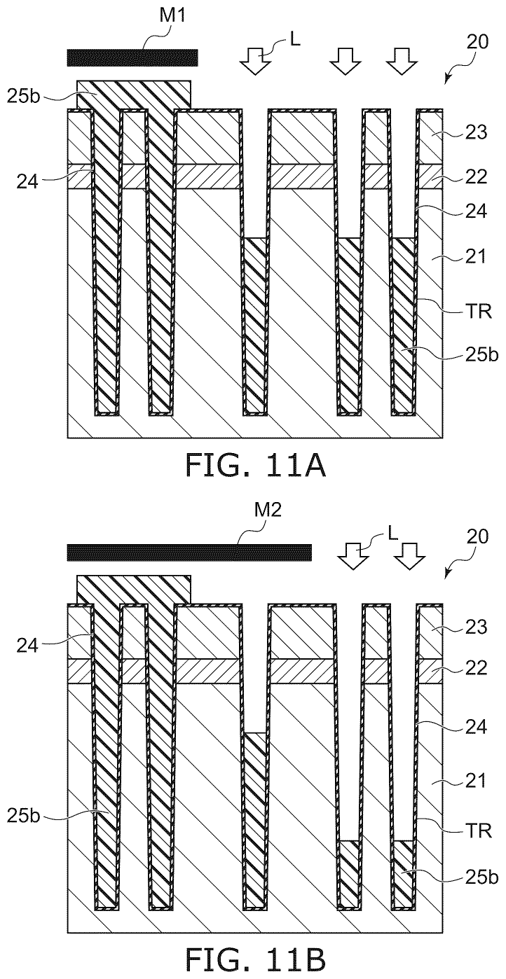

The semiconductor device 100 according to the embodiment will now be described with reference to FIGS. 11A to 13.

FIGS. 11A to 13 are cross-sectional views showing a method for manufacturing a semiconductor device according to a modification 2.

The lithography process of step S130 according to the modification 2 differs from those of the embodiments and the modification 1 described above. The modification 2 will now be described with focus on the differences.

In the lithography process of step S130 as shown in FIG. 11A, the positive resist 25b is coated onto the structure body 20, exposed by the light L to form a desired pattern by using a first mask M1, and developed. Then, as shown in FIG. 11B, the positive resist 25b is exposed by the light L using a second mask M2 to form a desired pattern, and then developed. As a result, the heights of the remaining positive resists 25b can be different between the multiple trenches TR in the cell part.

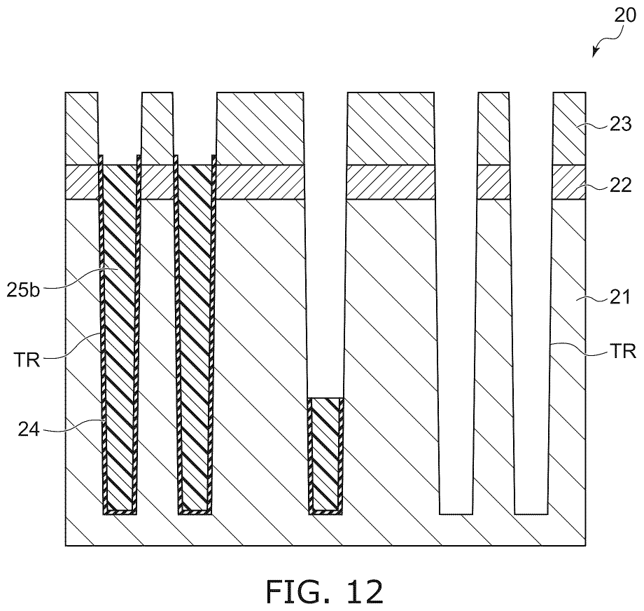

In the etching process of step S140 as shown in FIG. 12, the positive resists 25b that remain inside the trenches TR are caused to recede by CDE (Chemical Dry Etching). As a result, the positive resists 25b that remain inside the multiple trenches TR in the cell part can have different heights in different trenches TR. Subsequently, wet etching of the BSG film 24 on the upper surface of the structure body 20 and on the surface of the trench TR is performed. As a result, the BSG film 24 is removed at other locations different from the locations at which the positive resists 25b remain inside the trenches TR. Subsequently, the positive resists 25b that remain inside the trenches TR are removed.

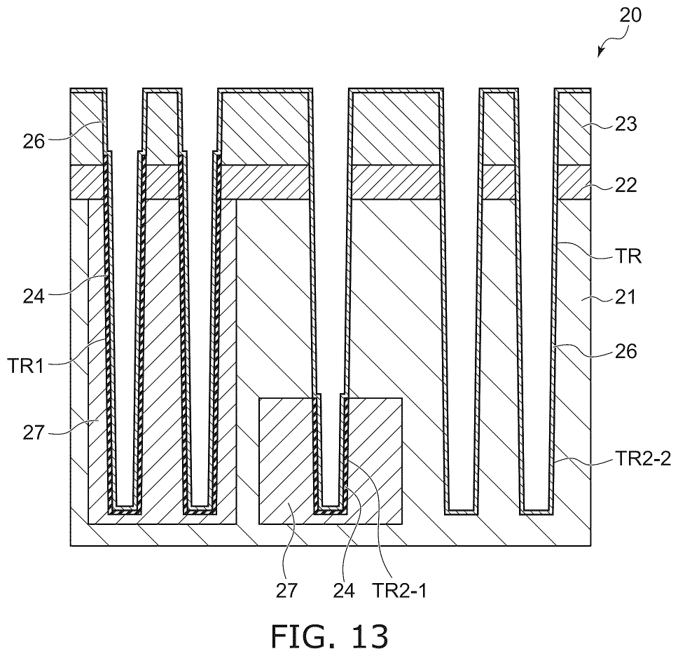

In the annealing process of step S150 as shown in FIG. 13, similarly to the embodiments above, the TEOS film 26 is formed as a protective film; and heat treatment of the structure body 20 is performed. As a result, solid-state diffusion of boron occurs from the remaining BSG film 24; and the p-layer 27 is formed at the periphery of the trench for the trench TR1 in the termination part and a first trench TR2-1 located in the cell part. On the other hand, the p-layer 27l is not formed at the periphery of a second trench TR2-2 located in the cell part. Thus, according to the modification 2, by using the positive resist 25b in the lithography process and by repeating the exposure and the development multiple times, the trench TR1 in the termination part, the first trench TR2-1 in the cell part, and the second trench TR2-2 in the cell part can have p-layers of different heights formed at the peripheries by changing the exposure amount between the termination part and the cell part. By using such a configuration, the p-layer that extends from the periphery of the upper end portion to the periphery of the lower end portion of the trench TR in the termination part functions as a guard ring; and electric field concentration at the surface vicinity of the boundary between the cell part and the termination part can be suppressed.

### 2. SECOND EMBODIMENT

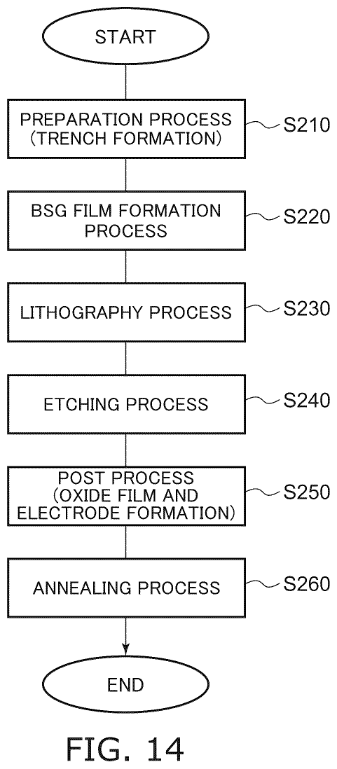

The semiconductor device 100 according to the embodiment will now be described with reference to FIGS. 14 to 17.

FIG. 14 is a flowchart showing the flow of the method for manufacturing the semiconductor device according to the second embodiment.

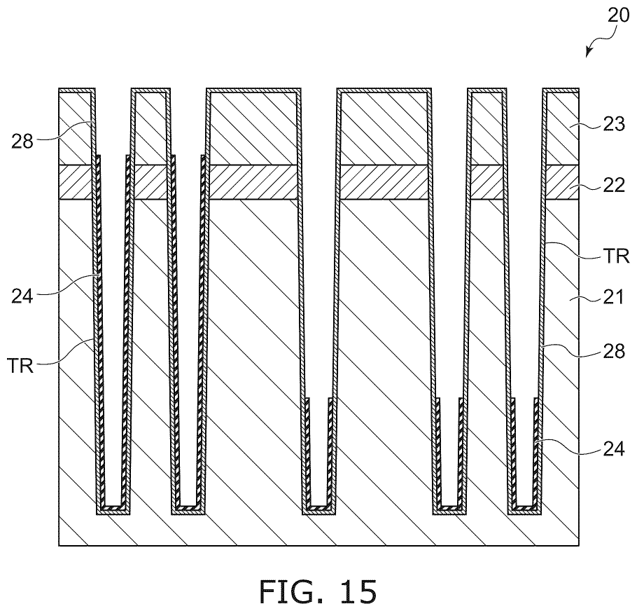

FIGS. 15 to 17 are cross-sectional views showing the method for manufacturing the semiconductor device according to the second embodiment.

As shown in FIG. 14, the second embodiment differs from the first embodiment above in that the sequence of the post process (S250) and the annealing process (S260) is interchanged. The second embodiment will now be described with focus on the differences. According to the second embodiment, the preparation process (S210), the lithography process (S230), and the etching process (S240) are similar to those of the first embodiment, and a description is therefore not repeated.

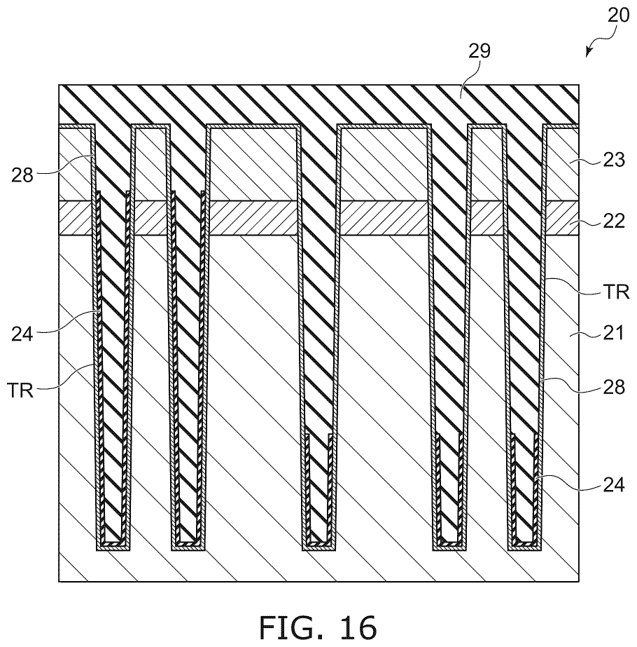

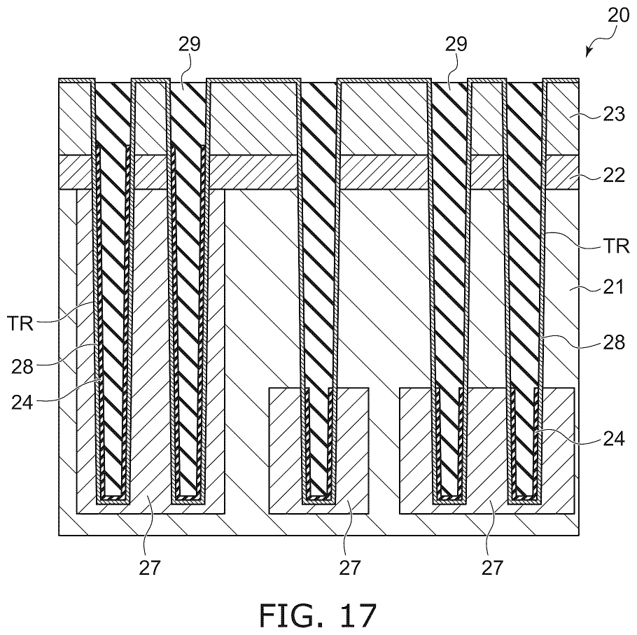

In step S220, before forming the BSG film 24, an oxide film 28 is formed at the upper surface of the structure body 20; and the BSG film 24 is formed at the surface of the oxide film 28. Subsequently, the lithography process (S230) and the etching process (S240) are performed. In step S250 as shown in FIG. 15, as a post process, the oxide film 28 is again formed at the upper surface of the structure body 20 and at portions of the trenches TR at which the BSG film 24 is not formed. Then, as shown in FIG. 16, a polysilicon layer 29 for forming the gate electrodes is formed on the structure body 20 by, for example, CVD. Subsequently, as shown in FIG. 17, the polysilicon layer 29 is caused to recede by etching.

In step S260, an annealing process is performed as shown in FIG. 17. In the annealing process, heat treatment of the structure body 20 is performed. As a result, solid-state diffusion of boron occurs from the remaining BSG film; and the p-layers 27 are formed at the peripheries of the trenches TR. Thus, according to the second embodiment, boron also is diffused into the polysilicon layer 29 that is used to form the gate electrodes 12 because solid-state diffusion by annealing is performed after the polysilicon layer 29 is formed.

Subsequently, the second semiconductor layer 10b, the third semiconductor layer 10c, and the fourth semiconductor layer 10d are formed by implanting impurities. Furthermore, the drain electrode 41 is provided at the lower surface of the semiconductor part 10; and the source electrode 42 and the source contact 51 are provided as the second electrode at the upper surface of the semiconductor part 10. As a result, the semiconductor device 100 according to the second embodiment is manufactured.

Thus, in the semiconductor device 100 according to the second embodiment, the BSG film 24 is formed between the trench TR and the gate electrode 12 formed inside the trench TR because the semiconductor device 100 is manufactured using the processes described above.

### 3. OTHER EMBODIMENTS

While embodiments of the disclosure are described above, applications of the technical idea of the disclosure are not limited to the examples described above. For example, although the BSG film 24 is formed in step S120 according to the embodiments above, the configuration is not limited to the example. In other words, it is sufficient for a material that can realize solid-state diffusion in the subsequent annealing process (S150) to be used; for example, another (insulating) film that includes boron may be used.

Although the TEOS film 26 is formed as a protective film in the structure body 20 before performing annealing treatment according to the embodiments above, the configuration is not limited to the example.

Although the semiconductor device 100 is a MOSFET according to the embodiments above, the semiconductor device 100 may be another semiconductor device. For example, an IGBT (Insulated Gate Bipolar Transistor) or a diode such as a FRD (Fast Recovery Diode), etc., may be used. For example, an IEGT and a FRD may be provided together. Thus, the technical idea of the disclosure is applicable to diverse types of semiconductor devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

Embodiments include the following aspects.

### Note 1

A method for manufacturing a semiconductor device, the method comprising:
preparing a structure body including a semiconductor part, a trench being formed in the structure body, the trench extending along a first direction;
forming a doped glass film at an upper surface of the structure body and at a surface of the trench;
forming a resist pattern on the structure body and performing lithography;
removing the doped glass film at a location other than a location at which the resist pattern remains; and
performing annealing treatment of the structure body including the doped glass film that remains.

### Note 2

The method according to note 1, wherein
the doped glass film is a BSG film.

### Note 3

The method according to note 1, wherein
the annealing treatment includes performing heat treatment of the structure body after forming a protective film on at least a portion of the structure body from which the doped glass film was removed.

### Note 4

The method according to note 3, wherein
the protective film is a TEOS film.

### Note 5

The method according to note 3, wherein
the protective film is formed also on the doped glass film.

### Note 6

The method according to any one of notes 1-5, further comprising:
removing the doped glass film that remains after the annealing treatment.

### Note 7

The method according to note 6, further comprising:
forming an oxide film at the surface of the trench after removing the doped glass film.

### Note 8

The method according to any one of notes 1-7, wherein
the annealing treatment includes performing heat treatment of the structure body after an oxide film and a polysilicon layer are formed at the upper surface of the structure body and at the surface of the trench.

### Note 9

The method according to any one of notes 1-8, wherein
in the lithography, exposure amounts are different between a cell part and a termination part adjacent to the cell part.

### Note 10

The method according to note 9, wherein
in the lithography, the exposure amounts are different between a first region of the cell part and a second region of the cell part.

### Note 11

A method for manufacturing a semiconductor device, the method comprising:
preparing a structure body including a semiconductor part, a trench being formed in the structure body, the trench extending along a first direction;
forming an oxide film at an upper surface of the structure body and at a surface of the trench;
forming a doped glass film on the oxide film;
forming a resist pattern on the structure body and performing lithography;
removing the doped glass film at a location other than a location at which the resist pattern remains; and
performing annealing treatment of the structure body including the doped glass film that remains.

### Note 12

The method according to note 11, wherein
the doped glass film is a BSG film.

### Note 13

The method according to note 11 or 12, further comprising:
forming a polysilicon layer on the oxide film and the doped glass film.

### Note 14

The method according to note 13, wherein
the annealing treatment is performed after forming the polysilicon layer.

### Note 15

A semiconductor device, comprising:
a first electrode;
a semiconductor part located on the first electrode, a plurality of trenches being formed in the semiconductor part along a first direction, the semiconductor part including
   a first semiconductor layer connected with the first electrode, the first semiconductor layer being of a first conductivity type,
   a second semiconductor layer located on the first semiconductor layer, the second semiconductor layer being of a second conductivity type,
   a third semiconductor layer located on the second semiconductor layer, the third semiconductor layer being of the first conductivity type,
   a first impurity layer that is of the second conductivity type and extends from a periphery of an upper end portion of the trench to a periphery of a lower end portion of the trench for a portion of the plurality of trenches, and
   a second impurity layer that is of the second conductivity type and is located at a periphery of a lower end portion of the trench for another portion of the plurality of trenches;
gate electrodes located inside the trenches;
an insulating part located on the semiconductor part and inside the trenches; and
a second electrode located on the semiconductor part, the second electrode being connected with the third semiconductor layer.

### Note 16

The device according to note 15, wherein
the first impurity layer is located in a termination part,
the termination part is adjacent to a cell part, and
the second impurity layer is located in the cell part.

### Note 17

The device according to note 15 or 16, wherein
BSG films are formed between surfaces of the trenches and the gate electrodes formed inside the trenches.

What is claimed is:

1. A method for manufacturing a semiconductor device, the method comprising:
preparing a structure body including a semiconductor part, a trench being formed in the structure body, the trench extending along a first direction;
forming a doped glass film at an upper surface of the structure body and at a surface of the trench;
forming a resist pattern on the structure body and performing lithography;
removing the doped glass film at a location other than a location at which the resist pattern remains; and
performing annealing treatment of the structure body including the doped glass film that remains.

2. The method according to claim 1, wherein
the doped glass film is a BSG film.

3. The method according to claim 1, wherein
the annealing treatment includes performing heat treatment of the structure body after forming a protective film on at least a portion of the structure body from which the doped glass film was removed.

4. The method according to claim 3, wherein
the protective film is a TEOS film.

5. The method according to claim 3, wherein
the protective film is formed also on the doped glass film.

6. The method according to claim 1, further comprising:
removing the doped glass film that remains after the annealing treatment.

7. The method according to claim 6, further comprising:
forming an oxide film at the surface of the trench after removing the doped glass film.

8. The method according to claim 1, wherein
the annealing treatment includes performing heat treatment of the structure body after an oxide film and a polysilicon layer are formed at the upper surface of the structure body and at the surface of the trench.

9. The method according to claim 1, wherein
in the lithography, exposure amounts are different between a cell part and a termination part adjacent to the cell part.

10. The method according to claim 9, wherein
in the lithography, the exposure amounts are different between a first region of the cell part and a second region of the cell part.

11. A method for manufacturing a semiconductor device, the method comprising:
preparing a structure body including a semiconductor part, a trench being formed in the structure body, the trench extending along a first direction;
forming an oxide film at an upper surface of the structure body and at a surface of the trench;
forming a doped glass film on the oxide film;
forming a resist pattern on the structure body and performing lithography;
removing the doped glass film at a location other than a location at which the resist pattern remains; and
performing annealing treatment of the structure body including the doped glass film that remains.

12. The method according to claim 11, wherein
the doped glass film is a BSG film.

13. The method according to claim 11, further comprising:
forming a polysilicon layer on the oxide film and the doped glass film.

14. The method according to claim 13, wherein
the annealing treatment is performed after forming the polysilicon layer.

15. A semiconductor device, comprising:
a first electrode;
a semiconductor part located on the first electrode, a plurality of trenches being formed in the semiconductor part along a first direction, the semiconductor part including
a first semiconductor layer connected with the first electrode, the first semiconductor layer being of a first conductivity type,
a second semiconductor layer located on the first semiconductor layer, the second semiconductor layer being of a second conductivity type,
a third semiconductor layer located on the second semiconductor layer, the third semiconductor layer being of the first conductivity type,
a first impurity layer that is of the second conductivity type and extends from a periphery of an upper end portion of the trench to a periphery of a lower end portion of the trench for a portion of the plurality of trenches, and
a second impurity layer that is of the second conductivity type and is located at a periphery of a lower end portion of the trench for another portion of the plurality of trenches;
gate electrodes located inside the trenches;
an insulating part located on the semiconductor part and inside the trenches; and
a second electrode located on the semiconductor part, the second electrode being connected with the third semiconductor layer.

16. The device according to claim 15, wherein
the first impurity layer is located in a termination part,
the termination part is adjacent to a cell part, and
the second impurity layer is located in the cell part.

17. The device according to claim 15, wherein
BSG films are formed between surfaces of the trenches and the gate electrodes formed inside the trenches.
